(19) United States
(12) Patent Application Publication
(10) Pub. No.: US 2012/0243287 A1
(43) Pub. Date: Sep. 27, 2012

(54) SEMICONDUCTOR MEMORY DEVICE CAPABLE OF IMPROVING DISTURBABILITY AND WRITABILITY

(75) Inventor: Atsushi Kawasumi, Kawasaki-shi (JP)

(73) Assignee: KABUSHIKI KAISHA TOSHIBA, Tokyo (JP)

(21) Appl. No.: 13/244,235

(22) Filed: Sep. 23, 2011

(30) Foreign Application Priority Data
Mar. 23, 2011 (JP) 2011-064935

(51) Int. Cl. G11C 5/06

(52) U.S. Cl. 365/72

(57) ABSTRACT

According to one embodiment, a semiconductor memory device includes memory cells and sense amplifiers. Each of the memory cells comprises a flip-flop circuit and first to fourth transistors. The flip-flop circuit includes a first storage node and a second storage node. The first and second transistors are connected between the first and second storage nodes of the flip-flop circuit and the first and second bit lines, respectively, and have gate electrodes are connected to the word line. The third and fourth transistors have gate electrodes connected to the word line and disconnect a feedback loop of the flip-flop circuit when the first and second transistors are selected. In data write, of a plurality of sense amplifiers, a sense amplifier including an unselected memory cell which is connected to the word line writes back data output from the unselected memory cell to the unselected memory cell.

### CROSS-REFERENCE TO RELATED APPLICATIONS

This application is based upon and claims the benefit of priority from prior Japanese Patent Application No. 2011-064935, filed Mar. 23, 2011, the entire contents of which are incorporated herein by reference.

### FIELD

Embodiments described herein relate generally to a semiconductor memory device such as a static random access memory (SRAM).

### BACKGROUND

Large-scale semiconductor integrated circuits (LSIs) used in portable devices need to reduce power consumption for a longer battery driven time. Power consumption can be reduced effectively by reducing the power supply voltage. However, recent advanced scaling has miniaturized elements, and element characteristics vary more and more. Even an SRAM used in the LSI also increases element characteristic variations, and the operating margin decreases. This makes it difficult to decrease the operating voltage of the SRAM. The operating voltage of the SRAM determines the power supply voltage of the overall LSI, and the power supply voltage of the LSI cannot be reduced.

In a conventional six-transistor SRAM cell, when a transfer transistor is selected as a transfer gate via a word line, the potential of a storage node which stores binary 0 in a flip-flop circuit connected to the transfer transistor rises slightly, making data in the flip-flop circuit unstable. Hence, reducing the power supply voltage damages data in the flip-flop circuit. This phenomenon is called data destruction by disturbance. To suppress the data destruction, the driving force of the transfer transistor needs to be decreased. However, this deteriorates data writability. The disturbability indicates the difficulty of changing data, and the writability indicates the ease of changing data. Therefore, the disturbability and writability have a trade-off relationship, and it is hard to satisfy them simultaneously.

### BRIEF DESCRIPTION OF THE DRAWINGS

FIG. 1 is a circuit diagram showing a semiconductor memory device according to the first embodiment;

FIG. 2 is a graph showing the simulation result of the write operation in the semiconductor memory device according to the first embodiment;

FIG. 3 is a graph showing the simulation result of the write operation in a conventional semiconductor memory device;

FIG. 4 is a circuit diagram showing a semiconductor memory device according to the second embodiment;

FIG. 5 is a graph showing the simulation result of the write operation in a semiconductor memory device as a precondition of the third embodiment;

FIG. 6 is a circuit diagram showing a semiconductor memory device according to the third embodiment;

FIG. 7 is a timing chart for explaining an operation in the third embodiment;

FIG. 8A is a graph showing the simulation result of the write operation in the absence of a coupling capacitor; and

FIG. 8B is a graph showing the simulation result of the write operation in the presence of a coupling capacitor according to the third embodiment.

### DETAILED DESCRIPTION

In general, according to one embodiment, a semiconductor memory device includes a plurality of pairs of bit lines, a word line, a plurality of memory cells, and a plurality of sense amplifiers. The pairs of bit lines include first and second bit lines. The word line is arranged to cross the pairs of bit lines. The memory cells are connected to the pairs of bit lines and the word line. The sense amplifiers are connected to the pairs of bit lines, respectively. Each of the memory cells comprises first and second storage nodes, first and second transistors, third and fourth transistors of a first conductivity type, fifth and sixth transistors of a second conductivity type, and seventh and eighth transistors. The first and second transistors have current paths connected between the first and second storage nodes and the first and second bit lines, respectively, and gate electrodes connected to the word line. The third and fourth transistors of the first conductivity type have current paths connected between the first and second storage nodes and a first power supply. The fifth and sixth transistors of the second conductivity type have current paths connected at one end to a second power supply, and gate electrodes connected to the second and first storage nodes, respectively, and connected to gate electrodes of the third and fourth transistors, respectively. The seventh and eighth transistors have current paths connected between the fifth and sixth transistors and the first and second storage nodes, respectively, and gate electrodes connected to the word line. When the word line is selected, the first and second transistors are turned on, and the seventh and eighth transistors are turned off to write data in the memory cells, a sense amplifier connected to an unselected pair of bit lines is connected to the word line to write back, in an unselected memory cell, data read from the unselected memory cell.

Embodiments will now be described with reference to the accompanying drawings.

An SRAM has a feature in which the storage state is held stably because a flip-flop circuit holds memory data. However, as described above, when a transfer transistor is turned on via a word line in, for example, data read at a reduced power supply voltage, a power supply voltage Vdd−Vth (Vth is the threshold voltage of an N-channel MOS transistor) is applied from a bit line to a storage node which stores binary 0, slightly raising the voltage of the storage node. The state of data stored in the cell becomes unstable, and in the worst case, data in the storage node is inverted, generating disturbance. In data write, the disturbance may occur even in an unselected memory cell connected to the word line. The embodiments prevent data destruction in a memory cell upon access to the word line.

### First Embodiment

The first embodiment arranges a sense amplifier for each column. In data write, write back is performed to latch, in the sense amplifier, data read from an unselected SRAM cell (to be simply referred to as a memory cell) to a pair of bit lines, and write back the latched data in the memory cell. Even at a reduced power supply voltage, this can improve data disturbability and further data writability in a selected memory cell.

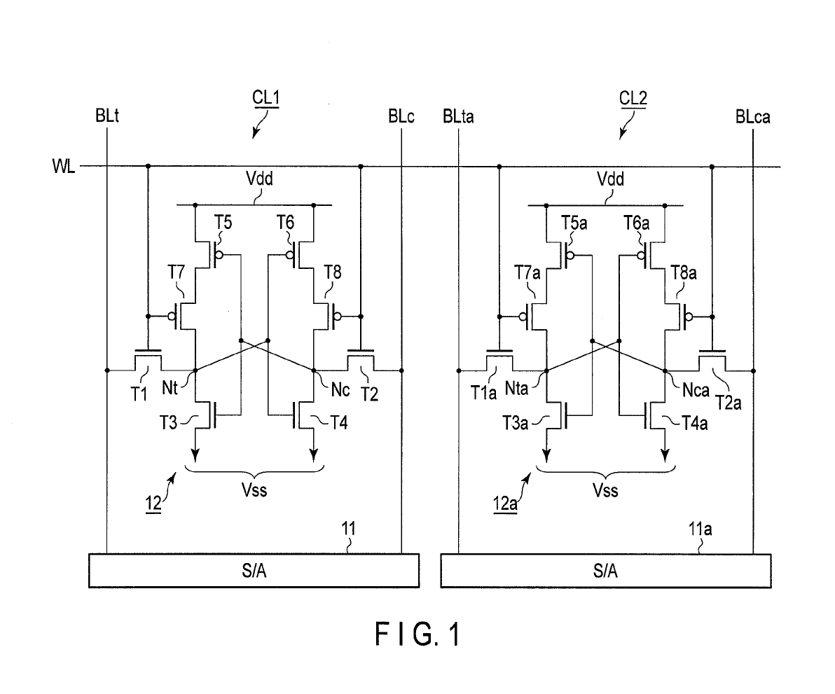

FIG. 1 shows an SRAM according to the first embodiment, and shows first and second columns CL1 and CL2 adjacent to each other. Since the first and second columns CL1 and CL2 have the same arrangement, the arrangement of the first column CL1 will be explained. The same reference numbers with a suffix “a” denote the same parts in the second column CL2, and a description thereof will not be repeated.

In the first column CL1, a pair of bit lines BLt and BLc are connected to a sense amplifier (S/A) 11. A plurality of memory cells 12 are connected to the pair of bit lines BLt and BLc. However, FIG. 1 shows only one memory cell 12 for descriptive convenience.

The memory cell 12 is formed from, e.g., eight transistors T1 to T8. The gate electrodes of N-channel MOS (NMOS) transistors T1 and T2 serving as transfer transistors are connected to a word line WL. The current paths of NMOS transistors T1 and T2 are connected at one end to bit lines BLt and BLc, respectively. The current paths of NMOS transistors T1 and T2 are connected at the other end to storage nodes Nt and Nc, respectively. The current paths of NMOS transistors T3 and T4 are connected at one end to storage nodes Nt and Nc, respectively. The current paths of NMOS transistors T3 and T4 are connected at the other end to a ground node Vss.

The current paths of P-channel MOS (PMOS) transistors T5 and T6 are connected at one end to the supply node of a power supply voltage Vdd. The current paths of PMOS transistors T5 and T6 are connected at the other end to storage nodes Nt and Nc via PMOS transistors T7 and T8, respectively. Further, the gate electrodes of PMOS transistors T5 and T6 are connected to the gates of NMOS transistors T3 and T4, respectively, and storage nodes Nc and Nt, respectively. The gate electrodes of PMOS transistors T7 and T8 are connected to the word line WL. When the word line becomes active (high), PMOS transistors T7 and T8 disconnect feedback loops in a flip-flop circuit formed by NMOS transistors T3 and T4 and PMOS transistors T5 and T6.

In an SRAM using a reduced power supply voltage, connecting many memory cells to a pair of bit lines requires a bit line with a long interconnect and increases the capacitance of the pair of bit lines. Time is taken to stabilize the voltage of the pair of bit lines by data read from a selected memory cell, decreasing the read rate. To prevent this, the embodiment needs to decrease the number of memory cells connected to a pair of bit lines. More specifically, the number of memory cells connected to a pair of bit lines is smaller than that in a conventional SRAM made up of six transistors.

### (Data Write Operation)

Write of data in a memory cell in the above arrangement will be explained. In this case, assume that data “1” is written to storage node Nt of a selected memory cell, and data “0” is written to storage node Nc. In this case, the sense amplifier 11 sets bit line BLt to data “1” (low=Vdd=0.5 V), and bit line BLc to data “0” (low=Vss=0 V).

In this state, when the word line WL goes high, NMOS transistors T1 and T2 serving as transfer transistors are turned on, and PMOS transistors T7 and T8 are turned off. In response to this, a feedback loop of NMOS transistor T1, PMOS transistor T6, and storage node Nc, and that of NMOS transistor T2, PMOS transistor T5, and storage node Nt are disconnected. Since NMOS transistors T1 and T2 are turned on, storage node Nt is charged to Vdd−Vth, and storage node Nc is charged to Vss. After that, the word line WL goes low to turn off NMOS transistors T1 and T2 and on PMOS transistors T5, T6, T7, and T8. Finally, storage node Nt is charged to Vdd (0.5 V), and storage node Nc is set to Vss.

In an unselected memory cell 12a connected to the word line WL on the second column CL2, assume that data “0” (low=Vss=0 V) is written to a storage node Nta, and data “1” (low=Vdd=0.5 V) is written to a storage node Nca.

In this state, before selecting the word line WL, bit lines BLta and BLca are precharged to, for example, the power supply voltage Vdd of 0.5 V. Then, the word line WL goes high. Similarly to the selected memory cell 12, NMOS transistors T1a and T2a serving as transfer transistors are turned on, and PMOS transistors T7a and T8a are turned off. Accordingly, a feedback loop of NMOS transistor T1a, a PMOS transistor T6a, and storage node Nca, and that of NMOS transistor T2a, a PMOS transistor T5a, and storage node Nta are disconnected. In this state, the voltages of storage nodes Nta and Nca are transferred to bit lines BLta and BLca via NMOS transistors T1a and T2a. As a result, bit line BLca stays high at 0.5 V, and bit line BLta goes low (0 V). Since the feedback loops are disconnected, as described above, inversion of data “0” in storage node Nta and data “1” in storage node Nca can be prevented.

While the potentials of bit lines BLta and BLca are stabilized, a sense amplifier 11a is enabled and starts the sense operation. The sense amplifier 11a fully swings the potentials of bit lines BLta and BLca, and the data are written back to storage nodes Nta and Nca via NMOS transistors T1a and T2a. This can prevent disturbance of the unselected memory cell connected to the word line WL.

In the embodiment, PMOS transistors T7 and T8 disconnect the feedback loops of the memory cell in the word line access state, preventing inversion of data in the memory cell. The sense amplifier can reliably sense data even if the sense timing of the sense amplifier in the embodiment is later than the timing when data is inverted and cannot be sensed in a conventional memory cell which does not disconnect the feedback loop.

### (Data Read Operation)

The data read operation is the same as the above-described write back operation of an unselected column. In data read, inversion of data in storage nodes Nt and Nc can be prevented, and correct data can be read. The read data are written back in the above-described way.

Even an unselected memory cell connected to a selected word line WL also performs the same operation as that of a selected memory cell, preventing data destruction.

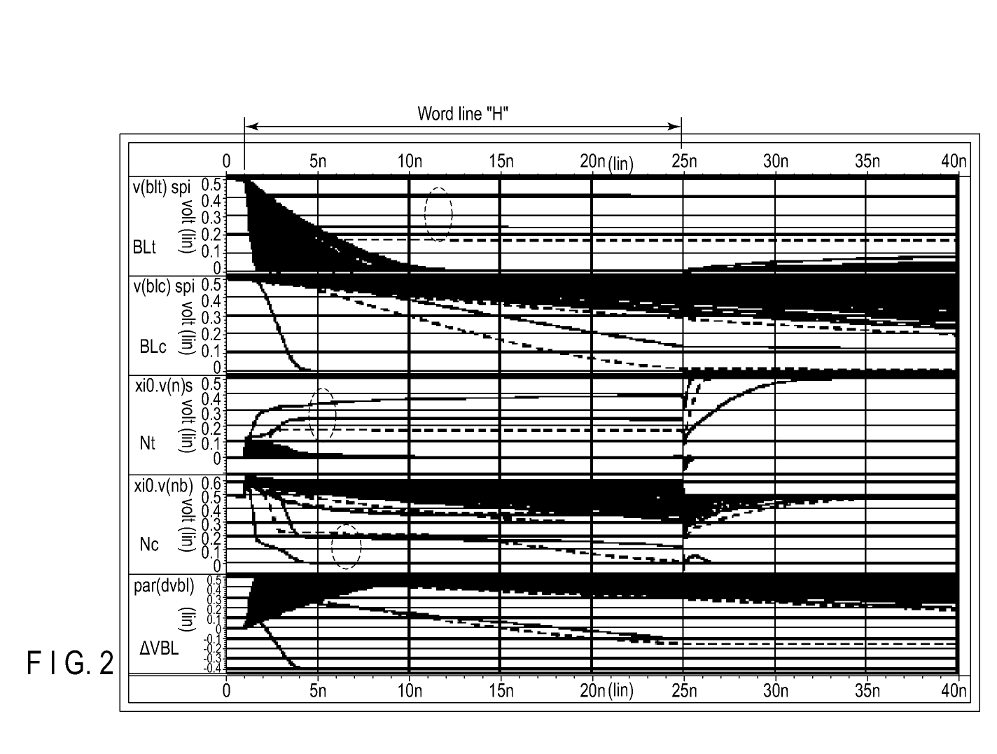

FIG. 2 shows the result of simulating the read operation of many unselected memory cells in the SRAM according to the embodiment. FIG. 2 shows changes of the potentials of bit lines BLt and BLc and storage nodes Nt and Nc.

Disturbance occurs in two cells, as represented by characteristics indicated by broken circles in FIG. 2. However, even when the power supply voltage is reduced, generation of disturbance can be prevented by disconnecting the feedback loop, as described above.

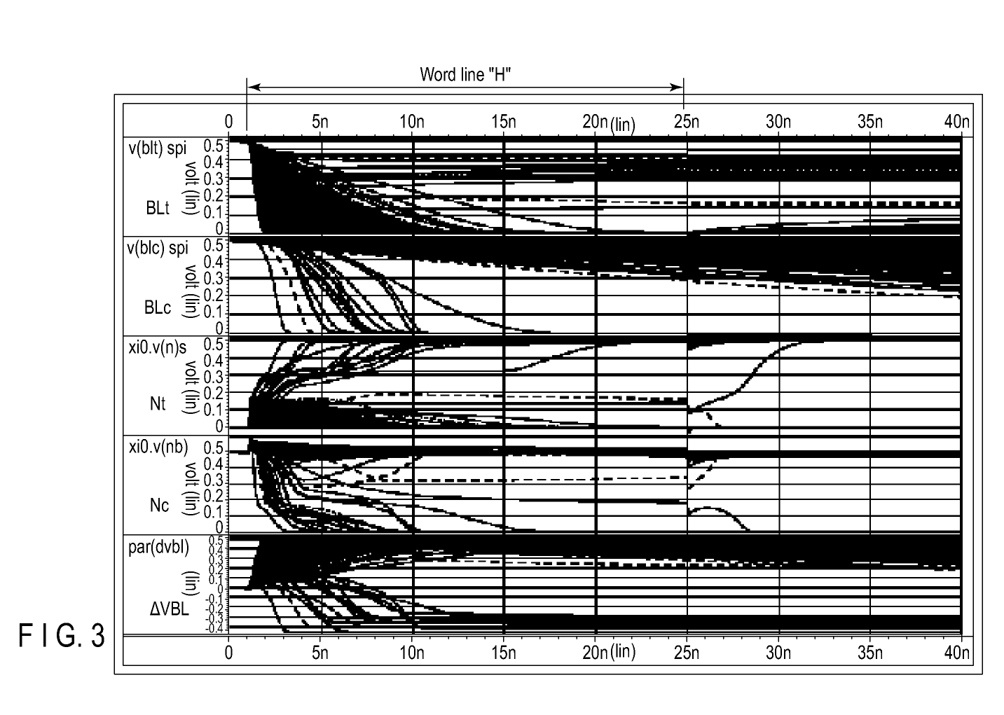

FIG. 3 shows the result of simulating the read operation of many unselected memory cells in a conventional SRAM having neither PMOS transistor T7 nor T8. FIG. 3 shows changes of the potentials of bit lines BLt and BLc and storage nodes Nt and Nc. As is apparent from FIG. 3, when the power supply voltage is reduced in the conventional SRAM which does not disconnect the feedback loop, the feedback operation reverses the potentials of storage nodes Nta and Nca, readily generating disturbance.

According to the embodiment, when the word line goes high, PMOS transistors T7 and T8 are turned off to disconnect feedback loops which form a flip-flop circuit in the memory cell 12. This can prevent destruction of data in storage nodes Nt and Nc. In addition, the sense amplifier 11 is connected to the pair of bit lines BLt and BLc. Data read from the memory cell 12 to the pair of bit lines BLt and BLc are fully swung by the sense amplifier 11 and written back to storage nodes Nt and Nc. Write back can be reliably performed, improving the reliability of data in the memory cell upon access to the word line in the low-voltage operation.

While the bit line potential is stable, the sense amplifiers 11 and 11a are enabled and start the sense operation. The sense amplifiers 11 and 11a start the sense operation at the same sense timing regardless of a column connected to the sense amplifier. Thus, the operation timings of the respective sense amplifiers are set to coincide with the latest column operation timing so that data of the latest column (memory cell) can be sensed. However, in the embodiment, the feedback loop of each memory cell is disconnected in access to the memory cell not to destroy data in the storage node. The potential of the bit line is stabilized within a shorter e than in the conventional SRAM. The timing to enable the sense amplifier can be advanced compared to the conventional SRAM. The read and write-back operations can be speeded up, and even the write rate can be increased.

Further, the embodiment can improve the disturbability in data read even when the power supply voltage is reduced and the potential difference between the equalization level of the bit line and the potential of the storage node becomes small.

### Second Embodiment

In the first embodiment, NMOS transistors T1 and T2 serve as transfer transistors. To the contrary, PMOS transistors serve as transfer transistors in the second embodiment.

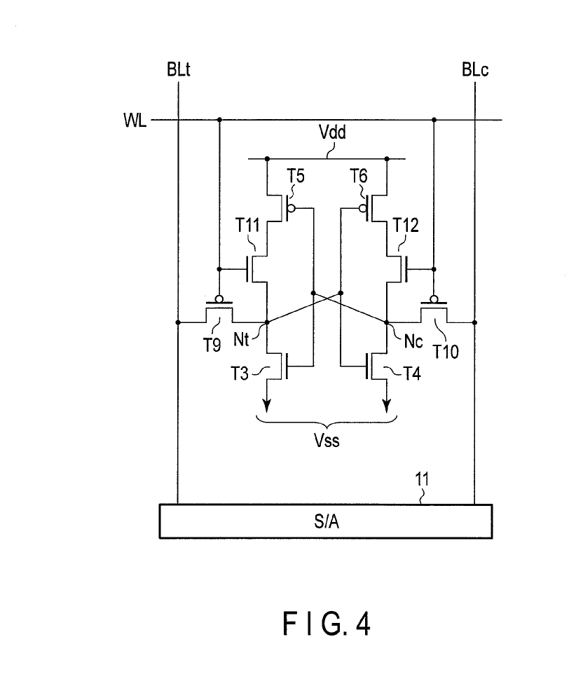

FIG. 4 shows the second embodiment. Referring to

FIG. 4, PMOS transistors T9 and T10 serve as transfer transistors. When PMOS transistors T9 and T10 serve as transfer transistors, a word line WL is made low in access. Hence, transistors which disconnect the feedback loops of the memory cell are not PMOS transistors T7 and T8 but NMOS transistors T11 and T12.

According to the second embodiment, PMOS transistors T9 and T10 serve as transfer transistors. The PMOS transistor can transfer a voltage without the influence of the threshold voltage, like the NMOS transistor. Even at a reduced power supply voltage, data can be reliably transferred from bit lines BLt and BLc to storage nodes Nt and Nc, and vice versa.

In this manner, PMOS transistors T9 and T10 in which local variations of the threshold voltage are small serve as transfer transistors. In access, data can be reliably held, improving the disturbability.

The use of PMOS transistors T9 and T10 with small variations of the threshold voltage as transfer transistors can reduce variations of the cell current at low voltage, suppressing a decrease in operation speed at low voltage.

### Third Embodiment

In the first embodiment, NMOS transistors T1 and T2 serve as transfer transistors. For example, when NMOS transistor T1 transfers the high of bit line BLt to storage node Nt, the voltage of storage node Nt rises only to Vdd−Vth, as described above. After the word line WL goes low, the voltage rises to Vdd via PMOS transistors T5 and T7. However, the two PMOS transistors T5 and T7 are connected between the supply node of the power supply voltage and storage node Nt. Even if PMOS transistor T5 is driven by charges of storage node Nc, storage node Nt may not be sufficiently charged.

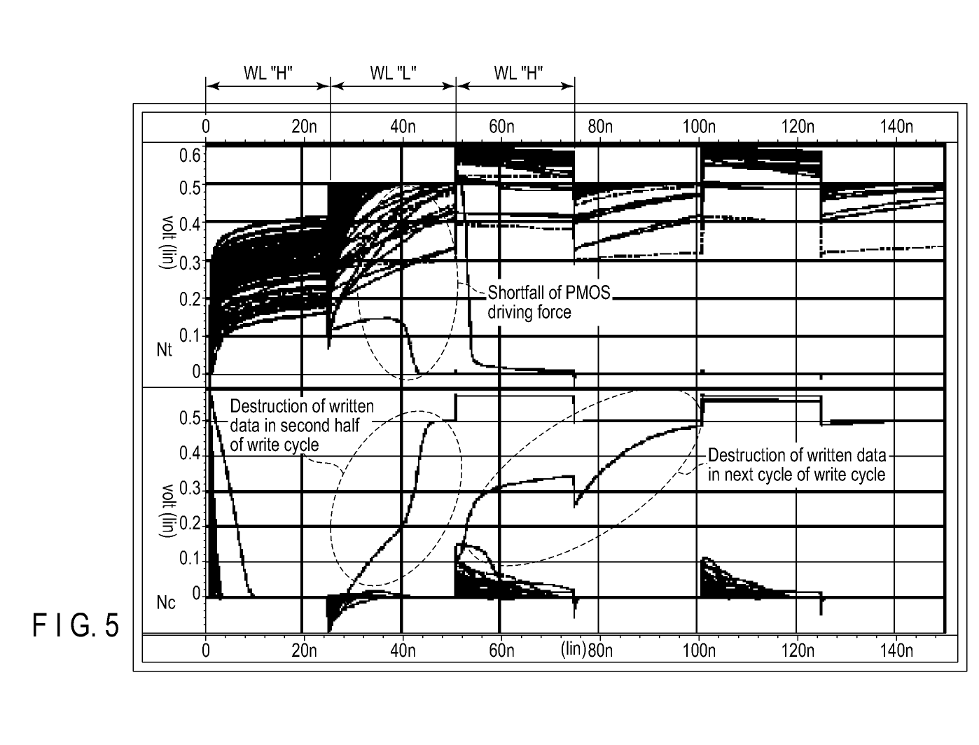

FIG. 5 shows an example of the simulation result of the write operation in the circuit according to the first embodiment. FIG. 5 shows changes of the voltages of storage nodes Nt and No in a plurality of memory cells. As shown in FIG. 5, when the word line WL is high, the voltage of storage node Nt rises to Vdd−Vth via NMOS transistor T1. When the word line WL goes low, the voltage of storage node Nt rises to Vdd (0.5 V) via PMOS transistors T5 and T7. At this time, in several memory cells indicated by broken circles, the voltage of storage node Nt does not reach Vdd owing to a deficiency of the driving forces of PMOS transistors T5 and T7.

Also, when the word line WL is made low, PMOS transistors T6 and T8 are not completely turned off for storage node Nc to which data “0” is to be written, because the voltage of storage node Nt does not reach Vdd, destroying data in storage node Nc.

Further, when the word line is made high in the next write cycle, written data is destroyed in storage node Nc.

The third embodiment allows a rise of the voltage of the storage node up to the power supply voltage while a word line WL is low.

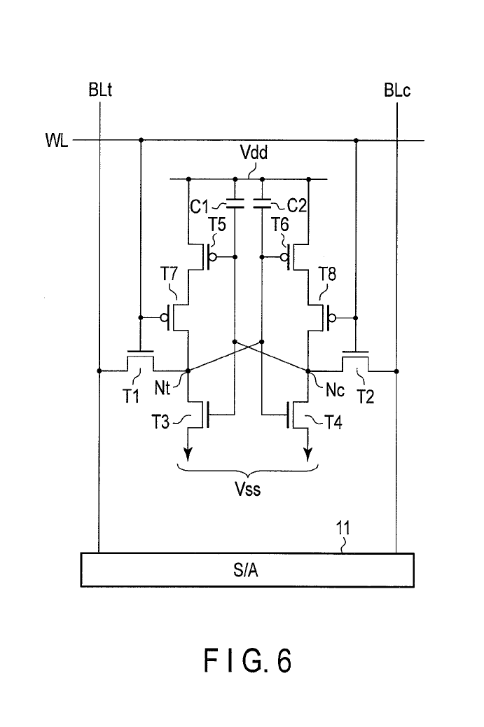

FIG. 6 shows the third embodiment. The same reference numbers as those in the first embodiment denote the same parts, and only a difference will be explained.

Referring to FIG. 6, coupling capacitors C1 and C2 are connected between the gate electrodes of PMOS transistors T5 and T6 and the supply node of a power supply Vdd, respectively. Each of capacitors C1 and C2 is formed from, e.g., metal interconnections and an insulating film in the cell layout.

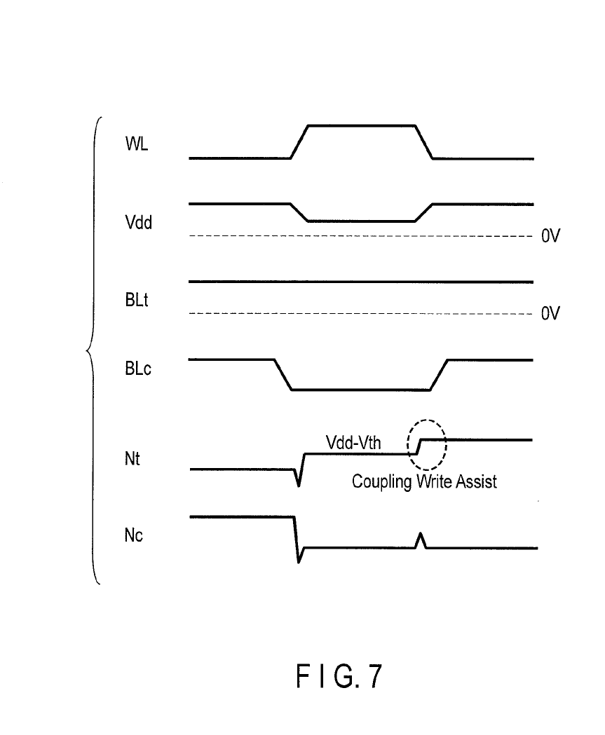

FIG. 7 shows the write operation of the circuit shown in FIG. 6. FIG. 7 shows a case in which data “1” is written to a storage node Nt and data “0” is written to a storage node Nc.

Bit line BLt is made high (Vdd), and bit line BLc is made low (Vss). Capacitors C1 and C2 are charged to the power supply Vdd.

In this state, when the word line WL goes high, PMOS transistors T7 and T8 are turned off to disconnect feedback loops, and NMOS transistors T1 and T2 serving as transfer transistors are turned on. Then, storage node Nt is charged to the voltage Vdd−Vth, and storage node Nc is set to a ground potential Vss.

After the word line WL goes low again, capacitor C1 applies −Vdd to the gate electrode of PMOS transistor T5 to assist the voltage of storage node Nc. The driving force of PMOS transistor T5 is enhanced, reliably charging storage node Nt to Vdd via PMOS transistors T5 and T7.

At this time, capacitor C2 also applies −Vdd to the gate electrode of PMOS transistor T6. Because of the voltage Vdd−Vth in storage node Nt, PMOS transistor T6 is slightly turned on. However, the voltage of storage node Nt changes to Vdd to turn off PMOS transistor T6, and storage node Nc holds binary 0.

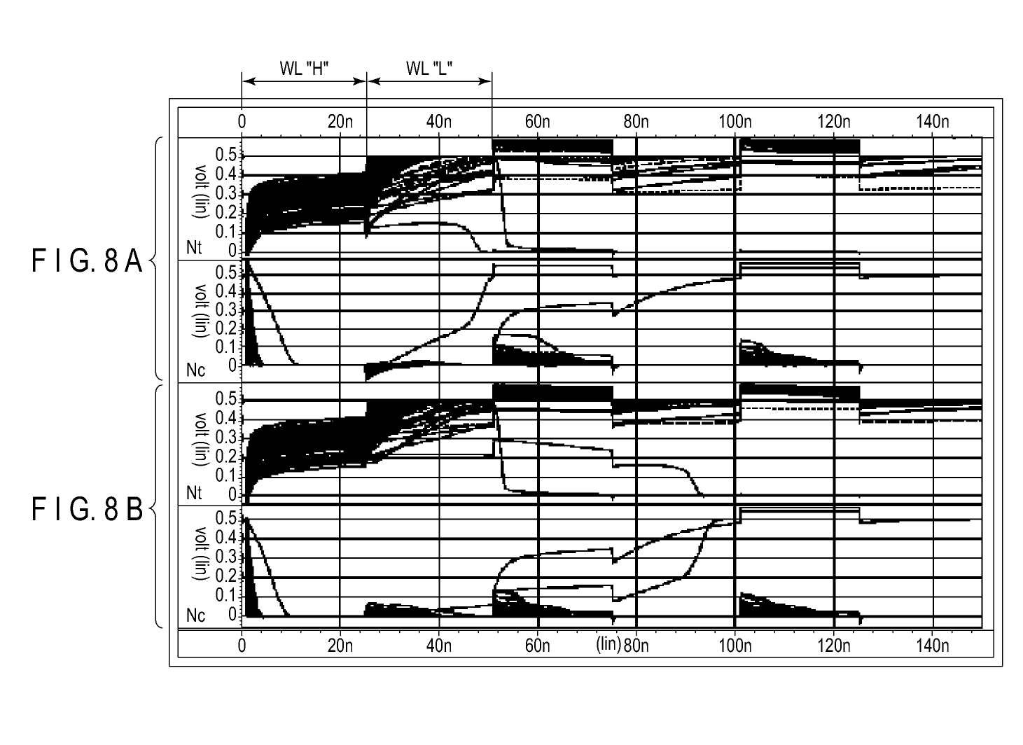

FIG. 8A shows the simulation result of the write operation in the absence of a coupling capacitor. FIG. 8B shows the simulation result of the write operation in the presence of a coupling capacitor according to the third embodiment. As is apparent from FIG. 8B, after the word line WL goes low, the potential of the storage node rises much more than in FIG. 8A. This operation remarkably appears in a memory cell having low write rate, and effectively prevents destruction of written data.

According to the third embodiment, the coupling capacitors C1 and C2 are connected between the gate electrodes of PMOS transistors T5 and T6 and the power supply node, respectively. This can enhance the driving forces of PMOS transistors T5 and T6 in data write. Storage nodes Nt and Nc can be reliably charged to Vdd quickly in an arrangement in which PMOS transistors T7 and T8 configured to disconnect feedback loops are connected between PMOS transistors T5 and T6 and storage nodes Nt and Nc, respectively.

Note that the second embodiment can be applied not only to the first embodiment but also to the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of pairs of bit lines including a bit line and a second bit line;
a word line arranged to cross the pairs of bit lines;
a plurality of memory cells connected to the pairs of bit lines and the word line, respectively; and
a plurality of sense amplifiers connected to the pairs of bit lines, respectively,
each of the memory cells comprising:
a first storage node and a second storage node;
a first transistor and second transistor having current paths connected between the first storage node and second storage node and the first bit line and second bit line, respectively, and gate electrodes connected to the word line;
a third transistor and fourth transistor of a first conductivity type having current paths connected between the first storage node and second storage node and a first power supply, respectively;
a fifth transistor and sixth transistor of a second conductivity type having current paths connected at one end to a second power supply, and gate electrodes connected to the second storage node and first storage node, respectively, and connected to gate electrodes of the third transistor and fourth transistor, respectively; and
a seventh transistor and eighth transistor having current paths connected between the fifth transistor and sixth transistor and the first storage node and second storage node, respectively, and gate electrodes connected to the word line,
wherein when the word line is selected, the first transistor and the second transistor are turned on, and the seventh transistor and the eighth transistor are turned off to write data to the memory cells, a sense amplifier connected to an unselected pair of bit lines is connected to the word line to write back, to an unselected memory cell, data read from the unselected memory cell.

2. The device according to claim 1, further comprising a first capacitor and second capacitor connected between gate electrodes of the fifth transistor and sixth transistor and the second power supply, respectively.

3. The device according to claim 1, wherein the first transistor and the second transistor are formed from transistors of the first conductivity type, and the seventh transistor and the eighth transistor are formed from transistors of the second conductivity type.

4. The device according to claim 1, wherein the first transistor and the second transistor are formed from transistors of the second conductivity type, and the seventh transistor and the eighth transistor are formed from transistors of the first conductivity type.

5. A semiconductor memory device comprising:
a plurality of pairs of bit lines including a first bit line and a second bit line;
a word line arranged to cross the pairs of bit lines;
a plurality of memory cells connected to the pairs of bit lines and the word line; and
a plurality of sense amplifiers connected to the pairs of bit lines, respectively,
each of the memory cells comprising:
a flip-flop circuit including a first storage node and a second storage node;
a first transistor and second transistor configured to be connected between the first storage node and second storage node of the flip-flop circuit and the first bit line and second bit line, respectively, and have gate electrodes connected to the word line; and
a third transistor and fourth transistor configured to have gate electrodes connected to the word line and disconnect a feedback loop of the flip-flop circuit when the first transistor and the second transistor are selected,
wherein in data write, of a plurality of sense amplifiers, a sense amplifier including an unselected memory cell which is connected to the word line writes back data output from the unselected memory cell to the unselected memory cell.

6. The device according to claim 5, wherein
the flip-flop circuit includes a fifth transistor and sixth transistor connected to a node to which a power supply voltage is applied, and a first capacitor and second capacitor connected between gate electrodes of the fifth transistor and sixth transistor and the node, respectively, and
the first capacitor and the second capacitor turn on the fifth transistor and the sixth transistor while the word line is not selected.

7. The device according to claim 5, wherein the first transistor and the second transistor are formed from transistors of a first conductivity type, and the third transistor and the fourth transistor are formed from transistors of a second conductivity type.

8. The device according to claim 5, wherein the first transistor and the second transistor are formed from transistors of a second conductivity type, and the third transistor and the fourth transistor are formed from transistors of a first conductivity type.
